(19) United States
(12) Patent Application Publication
(10) Pub. No.: US 2008/0232150 A1
(43) Pub. Date: Sep. 25, 2008

(54) Method and Structure for Implementing a Reprogrammable ROM

(76) Inventors: Roger Allen Booth, Wappingers Falls, NY (US); Chandrasekharan Kothandaraman, Hopewell Junction, NY (US); Alan James Leslie, Wappingers Falls, NY (US)

Correspondence Address: IBM CORPORATION;ROCHESTER IP LAW DEPT 917, 3605 HIGHWAY 52 N, ROCHESTER, MN, 55901-7829, US

(21) Appl. No.: 11/689,559

(22) Filed: Mar. 22, 2007

(51) Int. Cl. G11C 17/00

(52) U.S. Cl. 365/96

(57) ABSTRACT

A method and structure implementing a reprogrammable read only memory (ROM) include a pair of fuse elements having different lengths and selectively arranged to define an initial bit state. A group of a plurality of the pairs of fuse elements defines a predetermined data pattern of ones and zeros, providing initial states stored in the reprogrammable ROM. The reprogrammable ROM is reprogrammed when needed by selectively blowing a selected fuse or selected fuses to change the data pattern stored in the ROM.

### FIELD OF THE INVENTION

The present invention relates generally to the data processing field, and more particularly, relates to a method and structure for implementing a reprogrammable read only memory (ROM).

### DESCRIPTION OF THE RELATED ART

Several technologies may be used to produce a reprogrammable ROM, for example, an integrated FLASH memory. However, a significant disadvantage of using a flash memory is that a significant number of additional processing steps are required to implement a reprogrammable ROM.

U.S. Pat. No. 6,906,557 to Parker et al., issued Jun. 14, 2005, discloses a fuse sense circuit having a sense amplifier and a post amplifier or gain stage. The sense amplifier has a reference branch and one or more sense or fuse branches. The fuse sense circuit determines the state of the fuses using safe currents and provides much higher gain than prior art. The post amplifier is a scaled replica of the reference branch or one of the sense branches in that the devices in the post amplifier maintain the same ratio as similar devices in the reference branch, and components in the post amplifier each matches components in the reference branch. The sense amplifier output is interpreted by the post amplifier's matched gain stage and has a trip point that sufficiently tracks the reference voltage. The result is reduced process and voltage sensitivity, which allows lower differential fuse resistance to be accurately detected with a non-ideal sense amplifier. Multiple gain stages may be added to multiple sense branches for redundancy and single-ended sensing.

U.S. Pat. No. 6,590,825 to Tran et al., issued Jul. 8, 2003, discloses a non-volatile flash fuse element and an array of such elements that include fuses coupled to the input of a latch arranged as a differential comparator for constant current differential sensing. The fuse element includes a margining circuit that provides differential mass fuse margining. The margining circuit also allows the fuses to be stressed and screened. The fuse elements also provide constant current parallel programming.

A need exists for an effective mechanism for implementing a reprogrammable read only memory (ROM). It is desirable to provide such mechanism for implementing a reprogrammable read only memory (ROM) that is a fuse-based reprogrammable ROM.

As used in the following description and claims, it should be understood that the term fuse element means a non-volatile storage element that includes either an antifuse, which is a programmable element that provides an initial high resistance and when blown provides a selective low resistance or short circuit; or a fuse, which is a programmable element that provides an initial low resistance and when blown provides a selective high resistance or open circuit.

### SUMMARY OF THE INVENTION

Principal aspects of the present invention are to provide a method and structure for implementing a reprogrammable read only memory (ROM). Other important aspects of the present invention are to provide such method and structure for implementing a reprogrammable read only memory (ROM) substantially without negative effect and that overcome many of the disadvantages of prior art arrangements.

In brief, a method and structure are provided for implementing a reprogrammable read only memory (ROM). A pair of fuse elements having different lengths are selectively arranged to define an initial bit state. A group of the pairs of fuse elements define a predetermined data pattern of ones and zeros, providing initial states stored in the reprogrammable ROM. The ROM is reprogrammed by selectively blowing a selected fuse or selected fuses to change the data pattern stored in the ROM.

In accordance with features of the invention, the pair of fuse elements is arranged in a selected order to set the initial bit state of zero or one. For example, a first long fuse and a second short fuse define the initial bit state of a zero and a first short fuse and a second long fuse define the initial bit state of a one.

In accordance with features of the invention, sufficient sense margin exists between the long fuse and the short fuse for accurate identification of the initial bit state of zero or one. Sufficient sense margin exists between blown fuse element of either the long fuse and the short fuse for accurate identification of the blown fuse identifying a programmed bit state changing the data pattern stored in the ROM.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is a schematic diagram representation illustrating exemplary first and second fuse pairs respectively defining an initial bit state of zero and one in accordance with the preferred embodiment;

FIGS. 2A, and 2B illustrate exemplary novel reprogrammable ROM structures including a plurality of the exemplary first and second fuse pairs of FIG. 1 defining an exemplary predetermined data pattern of ones and zeros in accordance with the preferred embodiment; and

FIG. 3 is a graph illustrating exemplary sense margins between an initial pair of fuse elements of FIG. 1 and between a blown one of the pair of fuse elements and the other unblown one of the fuse elements in accordance with the preferred embodiment.

### DETAILED DESCRIPTION OF THE PREFERRED EMBODIMENTS

In accordance with features of the invention, an individual fuse element pair is set to an initial value, each pair is either set to one or set to zero without causing any impact on neighboring fuse elements. A pair of fuse elements having different lengths are selectively arranged to define the initial bit state of zero or one. A group of the pairs of fuse elements define a predetermined data pattern of ones and zeros, providing initial states stored in a re-programmable ROM of the invention. The ROM is reprogrammed when needed by selectively blowing a selected fuse or selected fuses to change the data pattern stored in the ROM.

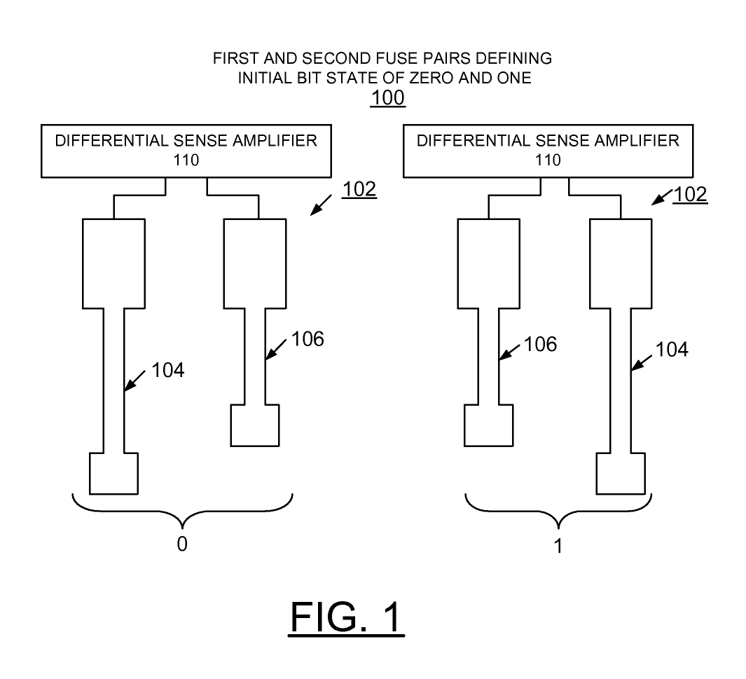

Having reference now to the drawings, in FIG. 1, there is shown an exemplary fuse apparatus generally designated by the reference character 100 including first and second fuse pairs 102 in accordance with the preferred embodiment. The illustrated first and second fuse pairs 102 respectively define an initial bit state of zero and an initial bit state of one.

Each of the first and second fuse pairs 102 includes a long fuse element 104 and a shorter fuse element 106. The pair 102 of fuse elements 104, 106 having different lengths are selectively arranged to define the initial bit state of zero or one.

As shown in the exemplary fuse apparatus 100, a first long fuse 104 and a second short fuse element 106 define the initial bit state of a zero. A first short fuse element 104 and a second long fuse element 106 define the initial bit state of a one.

A respective differential sense amplifier 110 connected to the fuse elements 104 and 106 of the illustrated first and second fuse pairs 102 senses to the fuse elements of the respective fuse pairs 102. The differential sense amplifier 110 identifies the initial bit state of zero or one for each of the fuse pairs 102.

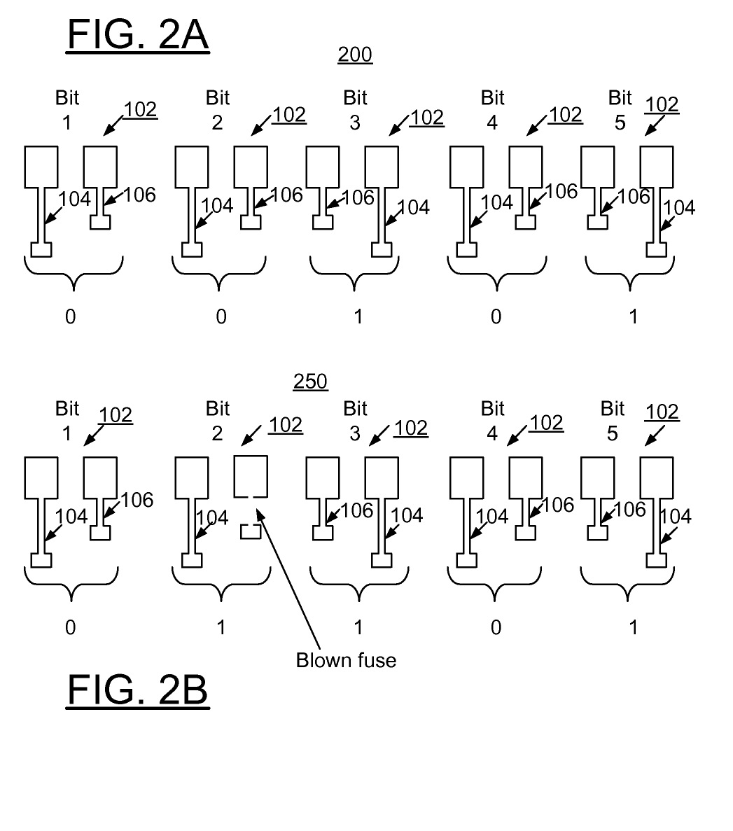

Referring also to FIGS. 2A, and 2B, there are shown respective exemplary novel reprogrammable ROM structures generally designated by the respective reference characters 200, 250 in accordance with the preferred embodiment.

FIG. 2A illustrates reprogrammable ROM structure 200 including a plurality of the exemplary first and second fuse pairs 102 of FIG. 1. Reprogrammable ROM structure 200 defines an exemplary initial predetermined data pattern of ones and zeros. As shown, the initial predetermined data pattern of Bits 1-5 is 00101.

FIG. 2B illustrates reprogrammable ROM structure 250 resulting after one of the fuse elements of fuse pair 102 defining Bit 2 is blown, changing Bit 2 from 0 to 1 to provide a reprogrammed predetermined data pattern stored in the reprogrammable ROM structure. As shown, the reprogrammed predetermined data pattern of Bits 1-5 is 01101.

In accordance with features of the invention, normal ROM operation advantageously is performed without blowing any fuse elements. During normal ROM operation, the differential sense amplifier 110 senses fuse elements and the data used by a processor (not shown), as required.

In accordance with features of the invention, if fuse apparatus or device 100 containing a reprogrammable ROM, such as reprogrammable ROM structure 200, is captured or the security is violated, the pattern in the reprogrammable ROM can be destroyed responsive to detecting violated security, to prevent unauthorized access to the data or operating the device. For example, in a communication device where the cryptography keys are stored in the reprogrammable ROM, when determined that the device had been tampered with, such as, captured by the enemy, the cryptography keys in the reprogrammable ROM advantageously would be randomized and the device would be rendered useless.

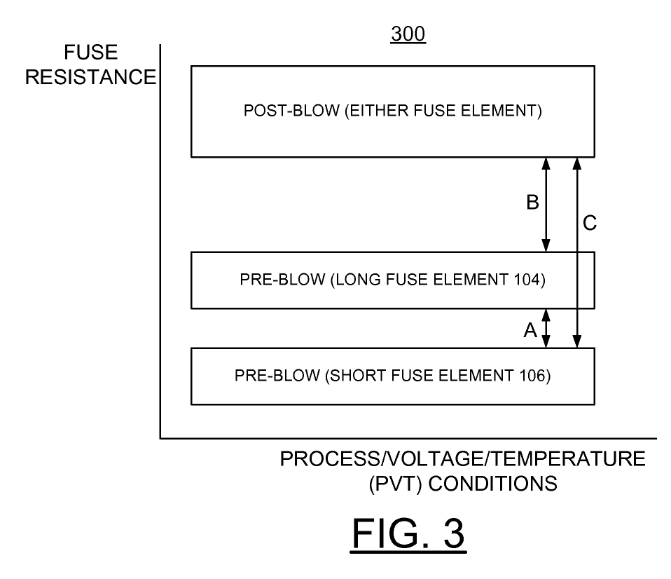

FIG. 3 illustrates exemplary sense margins between a particular initial pair 102 of fuse elements 104, 106 and between a blown one of the pair 102 of fuse elements 104, 106 and the other unblown one of the fuse elements in accordance with the preferred embodiment.

As illustrated in FIG. 3, sufficient sense margin exists between the long fuse and the short fuse for accurate identification of the initial bit state of zero or one. Sufficient sense margin exists between blown fuse element of either the long fuse and the short fuse for accurate identification of the blown fuse identifying a programmed bit state changing the data pattern stored in the ROM.

While the present invention has been described with reference to the details of the embodiments of the invention shown in the drawing, these details are not intended to limit the scope of the invention as claimed in the appended claims.

What is claimed is:

1. A structure for implementing a reprogrammable read only memory (ROM) comprising:
a pair of fuse elements, said pair including first and second fuse elements having different lengths and said first and second fuse elements being selectively arranged to define an initial bit state for said pair;
a group of a plurality of pairs of fuse elements; said group defining a predetermined data pattern of ones and zeros, said predetermined data pattern providing initial states stored in the ROM; and
said ROM being reprogrammed by selectively blowing a selected fuse for providing a changed data pattern stored in the ROM.

2. The structure as recited in claim 1 wherein said first and second fuse elements are selectively arranged to define said initial bit state with a selected order of a long fuse element and a short fuse element.

3. The structure as recited in claim 2 wherein a first long fuse element and a second short fuse element defines said initial bit state of a zero.

4. The structure as recited in claim 2 wherein a first short fuse and a second long fuse defines said initial bit state of a one.

5. The structure as recited in claim 1 wherein said first and second fuse elements have selected different lengths to provide a predefined sense margin for accurate identification of the initial bit state of zero or one.

6. The structure as recited in claim 1 wherein said first and second fuse elements have selected different lengths to provide a predefined minimum resistance difference providing a predefined sense margin for accurate identification of the initial bit state of zero or one.

7. The structure as recited in claim 1 wherein said first and second fuse elements have selected different lengths to provide a predefined minimum resistance difference providing a predefined sense margin for accurate identification of a blown fuse providing a reprogrammed data pattern stored in the ROM.

8. A method for implementing a reprogrammable read only memory (ROM) comprising the steps of.
providing a pair of fuse elements having different lengths and selectively arranging said first and second fuse elements to define an initial bit state for said pair;
providing a group of a plurality of pairs of fuse elements for defining a predetermined data pattern of ones and zeros, said predetermined data pattern providing initial states stored in the reprogrammable ROM; and
selectively blowing a selected fuse for providing a reprogrammed data pattern stored in the reprogrammable ROM.

9. The method as recited in claim 8 wherein providing a pair of fuse elements having different lengths includes providing said pair of fuse elements have selected different lengths to provide a predefined sense margin for accurate identification of the initial bit state of zero or one.

10. The method as recited in claim 8 wherein providing a pair of fuse elements having different lengths includes providing said pair of fuse elements have selected different lengths to provide a predefined minimum resistance difference between said pair of fuse elements.

11. The method as recited in claim 8 wherein providing a pair of fuse elements having different lengths includes providing said pair of fuse elements have selected different lengths to provide a predefined sense margin for accurate identification of a blown fuse providing a reprogrammed data pattern stored in the ROM.

12. The method as recited in claim 8 wherein selectively arranging said first and second fuse elements to define said initial bit state for said pair includes selectively arranged said first and second fuse elements with a selected order of a long fuse element and a short fuse element.

13. The method as recited in claim 12 includes providing a first long fuse element and a second short fuse element to define said initial bit state of a zero.

14. The method as recited in claim 12 includes providing a first short fuse and a second long fuse to define said initial bit state of a one.
